(19) United States
(12) Patent Application Publication
(10) Pub. No.: US 2020/0194095 A1
(43) Pub. Date: Jun. 18, 2020

(54) TEST METHOD FOR TRANSMIT PORT OF STORAGE DEVICES OF SYSTEM HOST

(71) Applicant: Super Micro Computer Inc., San Jose, CA (US)

(72) Inventors: Yueh-Ming LIU, San Jose (US); Hung-Chieh CHANG, San Jose (US); Tan-Hsin CHANG, San Jose (US); Hsiao-Chung CHEN, San Jose (US); Chih-Wei CHEN, San Jose, CA (US)

(21) Appl. No.: 16/220,253

(22) Filed: Dec. 14, 2018

(51) Int. Cl. G11C 29/56; G11C 16/26; G11C 16/10; G06F 12/0868; G06F 3/06

(52) U.S. Cl. CPC G11C 29/56; G11C 16/26; G11C 16/10; G11C 2029/5602; G06F 3/0614; G06F 3/0655; G06F 3/0679; G06F 12/0868

(57) ABSTRACT

A test method for a transmit port of storage devices of a system host, the system host includes a computing module, and the test method includes the steps of: coupling a test storage device to the transmit port of the computing module, wherein the test storage device includes a controller and a cache unit; providing, by the computing module, data to the test storage device through the transmit port to perform a storage testing mode; writing, by the controller, the data to the cache unit to complete the write operation, and then stops the write operation to complete the storage test; reading, by the computing module, the data provided from the test storage device for the computing module requested, performing a reading testing mode, and the controller only transmit the data from the cache unit to the computing module to complete a reading test.

### BACKGROUND

### Technical Field

The present disclosure relates to a test method, and more particularly to a test method for a transmit port of storage devices of a system host.

### Description of Related Art

The statements in this section merely provide background information related to the present disclosure and do not necessarily constitute prior art.

A solid-state storage device has a characteristic being arbitrarily placed in a computer system without affecting its normal operation. However, the current solid-state storage device has a certain lifetime limit with the number of readable times and writable times, for example, TBW (Terabytes Written) and DWPD (Drive Writes Per Day) are indices for evaluating the lifetime of the solid-state storage device. For system testers and server manufacturers, it is often necessary to perform a large number of read/write tests on the storage device due to the needs for frequent functional testing, burn-in aging verification, and assembly system hardware/software. If the general solid-state storage drive continues to be used, it will be difficult for the system tester and the server manufacturer to control the costs due to the foregoing the problem of lifetime limit.

Therefore, how to design a test method for a transmit port of storage devices of a system host to solve the technical problems above is an important subject studied by the inventors and proposed in the present disclosure.

### SUMMARY

The objective of the present disclosure is to provide a test method for a transmit port of storage devices of a system host. It may solve the problem of lifetime limit above with the general solid-state storage drive has a certain number of readable times and writable times in lifetime, and achieve the objective of improving the cost control for the relevant industry.

In order to achieve the objective, the present disclosure provides a test method for a transmit port of storage devices of a system host, the system host includes a computing module, and the test method including the following steps of: coupling a test storage device to the transmit port of the computing module, wherein the test storage device includes a controller and a cache unit coupled to the controller, providing, by the computing module, data to the test storage device through the transmit port, to perform a storage testing mode, writing, by the controller, the data to the cache unit to complete the write operation as the test storage device receives the data, and stops the write operation upon completion to complete the storage test, and reading, by the computing module, the data provided from the test storage device for the computing module requested, performing a reading testing mode, and the controller only transmit the data from the cache unit to the computing module to complete a reading test.

The efficacy and advantage of the test method for the transmit port of storage devices of the system host of the present disclosure, since the computing module and the controller of the test storage device communicate, the controller only performs the data with the cache unit for writing and reading, all used in the process only the cache unit being a random-access memory. Those skilled in the art may understand that the number of readable times and writable times in lifetime of the random-access memory are higher than those of the conventional solid-state drive, especially a non-volatile flash memory, for example, a NAND Flash. Therefore, through the proper configuration with the test method, the problem of lifetime above with the general solid-state drive has the certain number of readable times and writable times in lifetime may be solved, and achieve the objective of improving the cost control for the relevant industry.

### BRIEF DESCRIPTION OF DRAWING

FIG. 1 is a schematic diagram of a transmit port of storage devices of a system host of the present disclosure,

FIG. 2 and FIG. 3 are schematic diagrams showing the storage testing mode of the test method for a transmit port of storage devices of the system host of the present disclosure,

FIG. 4 and FIG. 5 are schematic diagrams showing the reading testing mode of the test method for a transmit port of storage devices of the system host of the present disclosure, and

FIG. 6 is a schematic flowchart of the test method for a transmit port of storage devices of the system host of the present disclosure.

### DETAILED DESCRIPTION

The technical content and detailed description of the present disclosure will be described below in conjunction with the drawings.

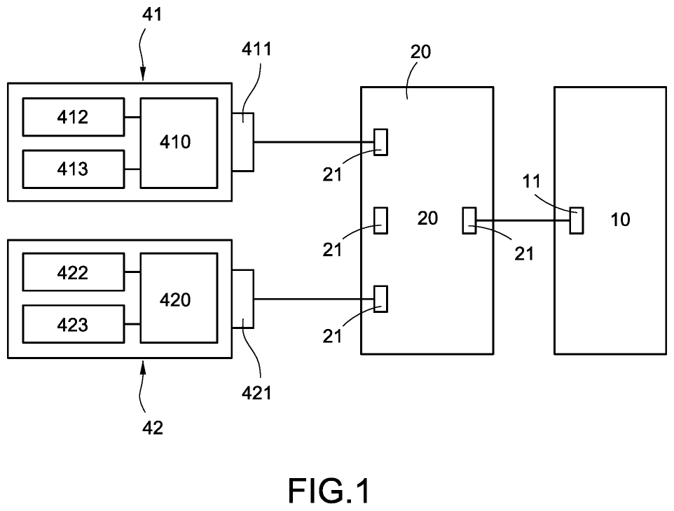

Referring to FIG. 1, a system host includes a computing module 10 and a backplane 20. The computing module 10 includes a transmit port 11, the backplane 20 has a plurality of connectors 21, and one of the connectors 21 is electrically connected to the transmit port 11 enabling the computing module 10 to be coupled to the backplane 20.

The backplane 20 may be a single-sided backplane or a double-sided midplane, which is compatible with general-purpose high-speed backplane architecture standards, such as CPCI, ATCA, MicroTCA, VPX, etc. In addition, each connector 21 may be a hybrid U.2 transmission interface compatible with three transmission protocols of SATA, SAS, and NVMe, or may be an independent storage device interface compatible with SATA, SAS, mSATA, M.2, SATA DOM, NF1, NGSFF or EGSFF. And each connector 21 may provide a hot-swapping function. In other embodiments, the backplane 20 may be replaced with a motherboard or an electronic circuit board having the connectors 21 with the same transmission function, and the computing module 10 may be selectively disposed on the motherboard or the electronic circuit board.

The system host may be a server, a personal computer (PC), a notebook computer (NB), a tablet computer, a smart phone, a personal digital assistant (PDA), or other electronic devices with the computing module 10.

When the user wants to test the transmit port 11 of storage devices of the system host, a test storage device 41 may be selectively used for testing procedures. The test storage device 41 includes a controller 410, a cache unit 413 coupled to the controller 410, a flash memory 412 coupled to the controller 410, and a transmission end 411 for coupling the test storage device 41 to other electronic devices. Similarly, the user may also selectively use the two test storage devices 41, 42 in the meantime, i.e., a first test storage device 41 and a second test storage device 42 for testing procedures. The second test storage device 42 is substantially the same as the first test storage device 41. The only difference is that the controller 410 and the controller 420 are compatible with different transmission protocols, and the transmission protocol may be any one of SATA, SAS, and NVMe.

In particular, the cache unit 413 may be a random-access memory. Therefore, the data stored in the cache unit 413 would be eliminated as the cache unit 413 loses operating power. Alternatively, the cache unit 413 may be, for example but not limited to, a dynamic random-access memory (DRAM), or a static random-access memory (SRAM).

The flash memory 412 may be a non-volatile flash memory, for example, a NAND Flash.

Further, the test storage devices 41, 42 may be used without the flash memory 412 according to the user's needs.

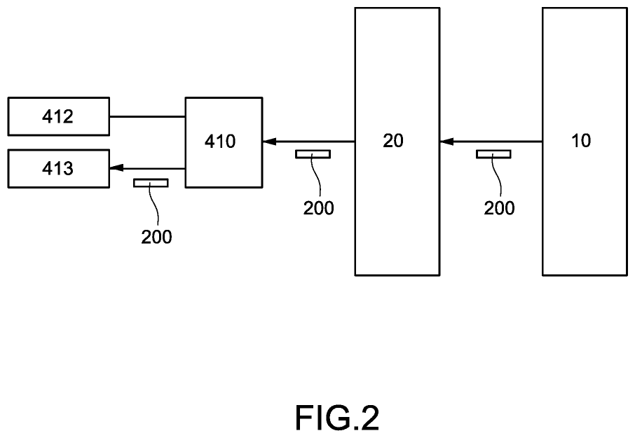

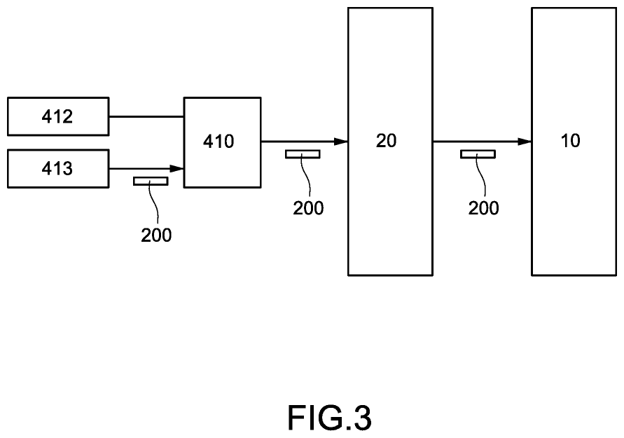

The following is a detailed description of the storage test method and the reading test method. Referring to FIG. 2 and FIG. 3, when the user needs to perform the storage test mode on the transmit port 11 of the computing module 10 of the system host, the user uses the test storage device 41 to plug one of the connectors 21 on the backplane 20 to perform the storage test. The test storage device 41 may be electrically connected to the computing module 10 through the transmit port 11 and then to perform a storage test mode. The computing module 10 provides data 200 to the test storage device 41 through the transmit port 11 and the connector 21 of the backplane 20. When the test storage device 41 receives the data 200, the controller 410 writes the data 200 to the cache unit 413, and then stops the write operation to complete the storage test.

When the user performs a reading testing mode, the test storage device 41 is still coupled to one of the connectors 21 of the backplane 20. And the computing module 10 requests the test storage device 41 to provide the data 200 for the computing module 10 to read according to the user's needs. The controller 410 only transmits the data 200 from the cache unit 413 to the computing module 10 to complete the reading test.

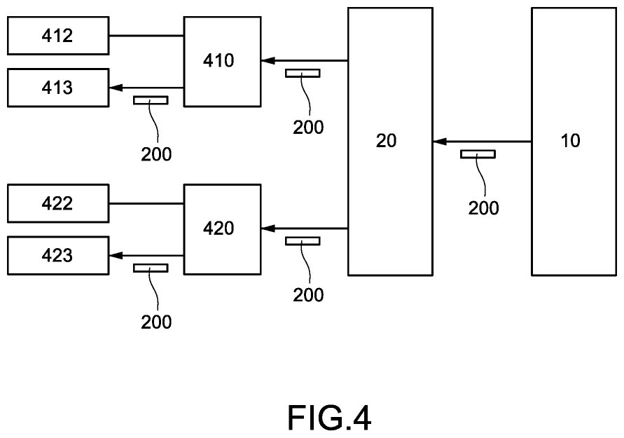

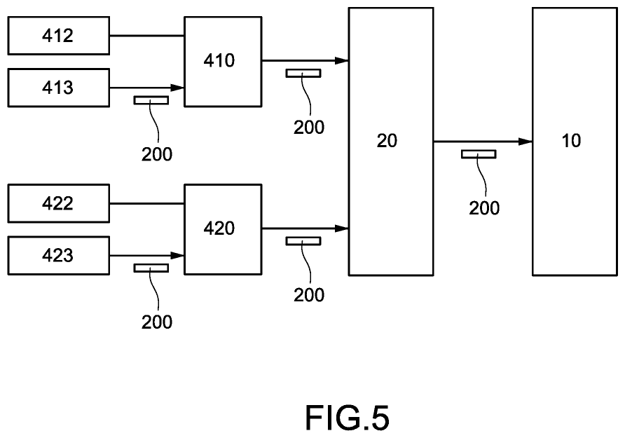

Referring to FIG. 4 and FIG. 5, which show another embodiment of the present disclosure. If the user needs to test two test storage devices 41, 42 at the same time, it is similar to the described method of using a single test storage device 41 above. The user first inserts the two test storage devices 41, 42 into the connectors 21 on the backplane 20 to electrically connect the computing module 10 through the transmit port 11, and then performs a storage testing mode. The computing module 10 provides data 200 to the test storage devices 41, 42 in the meantime through the transmit port 11 and the connector 21 of the backplane 20. When the test storage devices 41, 42 receive the data 200, the controllers 410, 420 writes the data 200 to the cache units 413, 423, and then stops the write operation to complete the storage test.

Similarly, when the user performs a reading testing mode, the test storage devices 41, 42 are still coupled respectively to the connectors 21 of the backplane 20. And the computing module 10 requests the test storage devices 41, 42 to provide the data 200 for the computing module 10 to read according to the user's needs. The controllers 410, 420 only transmit the data 200 from the cache units 413, 423 to the computing module 10 to complete the reading test.

When the storage test or reading test is performed, the test storage devices 41, 42 may be stored or read in the meantime, or may be sequentially stored or read according to the user's needs.

Further, in the foregoing test method, since the flash memories 412, 422 of the test storage devices 41, 42 are not used for storing and reading, the readable times and writable times are not reduced, and therefore the lifetime of the test storage devices 41, 42 is not reduced. In other words, in the storage test, the controllers 410, 420 only write the data 200 into the cache units 413, 423 rather than the flash memories 412, 422. In the reading test, the controllers 410, 420 only read the data 200 stored in the cache units 413, 423 rather than the flash memories 412, 422. Therefore, it may be ensured that when the test storage devices 41, 42 are solid-state drive (SSD), the test method may be used to extend the lifetime of the test storage devices 41, 42.

In particular, when the computing module 10 that is compatible with hybrid transmission protocols, that is, the computing module 10 may support transmission protocols such as SATA, SAS, NVMe, and so on, and may perform the storage testing mode and perform the reading testing mode for the test storage devices 41, 42 in the meantime.

The connector 21 on the backplane 20 may be a U.2 transmission interface. Therefore, the test storage devices 41, 42 may be compatible with different transmission protocols respectively such as SAS and NVMe, thereby testing the computing module 10 and the transmit port 11 in the meantime may normally perform storage and reading operations according to different transmission protocols of the test storage devices 41, 42.

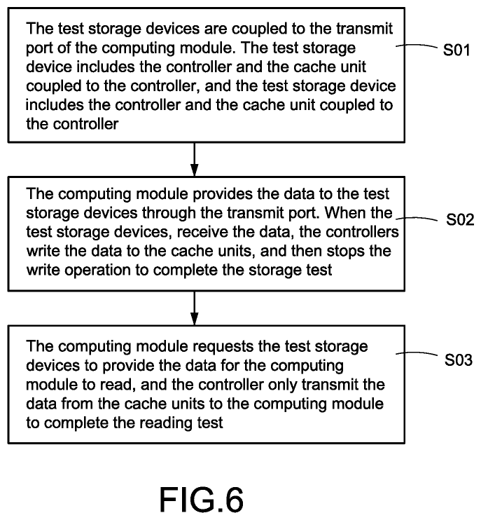

Please refer to FIG. 6, which is a flowchart of the test method for a transmit port of storage devices of the system host according to the present disclosure. Initially, the test storage devices 41, 42 are coupled to the transmit port 11 of the computing module 10. The test storage device 41 includes the controller 410 and the cache unit 413 coupled to the controller 410, and the test storage device 42 includes the controller 420 and the cache unit 423 coupled to the controller 420 (step S01). Afterward, performing a storage testing mode. The computing module 10 provides the data 200 to the test storage devices 41, 42 through the transmit port 11. When the test storage devices 41, 42 receive the data 200, the controllers 410, 420 write the data 200 to the cache units 413, 423, and then stops the write operation to complete the storage test (step S02). Afterward, performing a reading testing mode. The computing module 10 requests the test storage devices 41, 42 to provide the data 200 for the computing module 10 to read, and the controller 410, 420 only transmit the data 200 from the cache units 413, 423 to the computing module 10 to complete the reading test (step S03).

Therefore, through the proper configuration with the test method, the lifetime problem above with the general solid-state drive has a certain number of readable times and writable times in lifetime may be solved, and achieve the objective of improving the cost control for the relevant industry.

The above is only a detailed description and drawings of the preferred embodiments of the present disclosure, but the features of the present disclosure are not limited thereto, and are not intended to limit the present disclosure.

What is claimed is:

1. A test method for a transmit port of storage devices of a system host, the system host comprising a computing module, and the test method comprising the following steps of:
coupling a test storage device to the transmit port of the computing module, wherein the test storage device includes a controller and a cache unit coupled to the controller,
providing, by the computing module, data to the test storage device through the transmit port, to perform a storage testing mode,
writing, by the controller, the data to the cache unit to complete the write operation as the test storage device receives the data, and stops the write operation upon completion to complete the storage test, and
reading, by the computing module, the data provided from the test storage device for the computing module requested, performing a reading testing mode, and the controller only transmit the data from the cache unit to the computing module to complete a reading test.

2. The test method for the transmit port of storage devices of the system host in claim 1, wherein the test storage device further comprises a flash memory coupled to the controller, and the controller writes the data to the cache unit rather than the flash memory as the storage testing mode is performed.

3. The test method for the transmit port of storage devices of the system host in claim 2, wherein the controller reads the data stored in the cache unit rather than the flash memory and transmits the data to the computing module as the reading testing mode is performed.

4. The test method for the transmit port of storage devices of the system host in claim 3, wherein the controller is driven by a built-in firmware to perform the storage testing mode and the reading testing mode.

5. The test method for the transmit port of storage devices of the system host in claim 4, wherein the cache unit is a random-access memory, and the data stored in the cache unit are eliminated as the cache unit loses operating power.

6. The test method for the transmit port of storage devices of the system host in claim 5, wherein the number of the test storage devices is two, the two test storage devices are compatible with different transmission protocols and respectively coupled to the computing module, the computing module performs the storage testing mode and the reading testing mode in the meantime according to a plurality of built-in transmission protocols for each test storage device.
